(19) United States
(12) Patent Application Publication
(10) Pub. No.: US 2025/0079291 A1
(43) Pub. Date: Mar. 6, 2025

(54) SEMICONDUCTOR DEVICE

(71) Applicant: Mitsubishi Electric Corporation, Tokyo (JP)

(72) Inventors: Shinji SAKAI, Tokyo (JP); Daisuke NAGAOKA, Hyogo (JP)

(73) Assignee: Mitsubishi Electric Corporation, Tokyo (JP)

(21) Appl. No.: 18/782,358

(22) Filed: Jul. 24, 2024

(30) Foreign Application Priority Data
Sep. 6, 2023 (JP) 2023-144312

(51) Int. Cl. H01L 23/498; H01L 23/00; H01L 23/29; H01L 25/16

(52) U.S. Cl. CPC H01L 23/49861; H01L 23/293; H01L 24/08; H01L 24/09; H01L 24/48; H01L 24/49; H01L 25/16; H01L 2224/08155; H01L 2224/09152; H01L 2224/48137; H01L 2224/48179; H01L 2224/49107; H01L 2224/49173; H01L 2924/13091

(57) ABSTRACT

A semiconductor device includes: at least one control chip provided at a position overlapping a first die pad in plan view and electrically connected to the first die pad; a plurality of power chips mounted to respective second die pads; a plurality of circuit patterns and a plurality of wire pads arranged on a top surface of an insulating substrate provided on a top surface of the first die pad; a plurality of first control wires electrically connecting the plurality of wire pads and the at least one control chip; and a plurality of second control wires electrically connecting the at least one control chip and the plurality of power chips.

### BACKGROUND OF THE INVENTION

### Field of the Invention

The present disclosure relates to transfer-molded power modules.

### Description of the Background Art

A transfer-molded power module has a structure in which a power chip and a control chip to control the power chip are incorporated and they are encapsulated by an insulating molding resin. Transfer-molded power modules include a lead frame-type transfer-molded power module in which a die pad and terminals of the control chip are formed from a lead frame molded from a copper plate and circuits are connected by wires (see Japanese Patent Application Laid-Open No. 2021-141237, for example).

The lead frame-type transfer-molded power module has a problem in that a wire bonding the control chip and the power chip is deformed during infusion with the molding resin, comes into contact with the lead frame, and causes insulation failure.

### SUMMARY

It is an object of the present disclosure to suppress insulation failure of a lead frame-type transfer-molded power module.

A semiconductor device according to the present disclosure includes a first die pad, at least one control chip, a plurality of control-side terminals, a plurality of second die pads, a plurality of power chips, a plurality of power-side terminals, an insulating substrate, a plurality of circuit patterns, a plurality of wire pads, a plurality of first control wires, a plurality of second control wires, and a molding resin. The at least one control chip is provided on a top side of the first die pad and at a position overlapping the first die pad in plan view and is electrically connected to the first die pad. The plurality of control-side terminals are to supply a signal to the at least one control chip. The plurality of power chips are mounted to the respective second die pads and controlled by the at least one control chip. The plurality of power-side terminals are connected to the respective second die pads. The insulating substrate is provided on a top surface of the first die pad. The plurality of circuit patterns are arranged on a top surface of the insulating substrate, electrically connected to the control-side terminals, and conductive. The plurality of wire pads are arranged on the top surface of the insulating substrate and are electrically connected to the respective circuit patterns. The plurality of first control wires electrically connect the plurality of wire pads and the at least one control chip. The plurality of second control wires electrically connect the at least one control chip and first connection regions of the plurality of power chips. The molding resin encapsulates the at least one control chip, the plurality of power chips, the plurality of first control wires, and the plurality of second control wires. The first die pad, the plurality of second die pads, the plurality of control-side terminals, and the plurality of power-side terminals are formed from a lead frame.

According to the semiconductor device according to the present disclosure, a control signal is transmitted from the plurality of control-side terminals to the at least one control chip via the plurality of circuit patterns, the plurality of wire pads, and the plurality of first control wires. According to such a configuration, the plurality of first control wires can be shortened by arranging the plurality of wire pads close to the at least one control chip. Deformation of the plurality of first control wires and insulation failure associated with deformation during infusion with the molding resin can thereby be suppressed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a semiconductor device according to Embodiment 1;

FIG. 2 is a cross-sectional view of the semiconductor device according to Embodiment 1;

FIG. 3 is a top view of a semiconductor device according to Embodiment 2;

FIG. 4 is a cross-sectional view of the semiconductor device according to

Embodiment 2; and

FIG. 5 is a top view of a semiconductor device according to Embodiment 3.

### DESCRIPTION OF THE PREFERRED EMBODIMENTS

### A. Embodiment 1

### A-1. Configuration

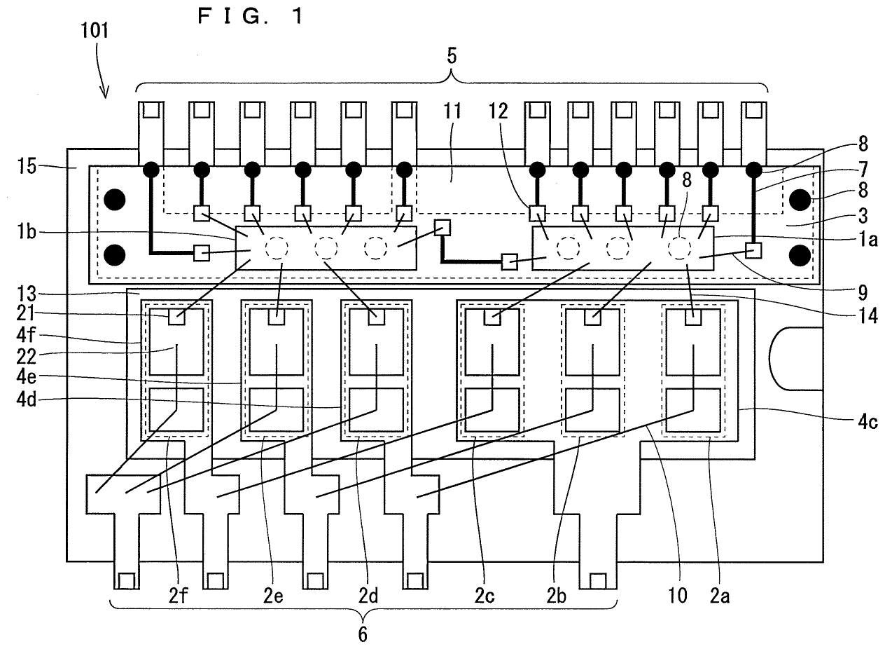

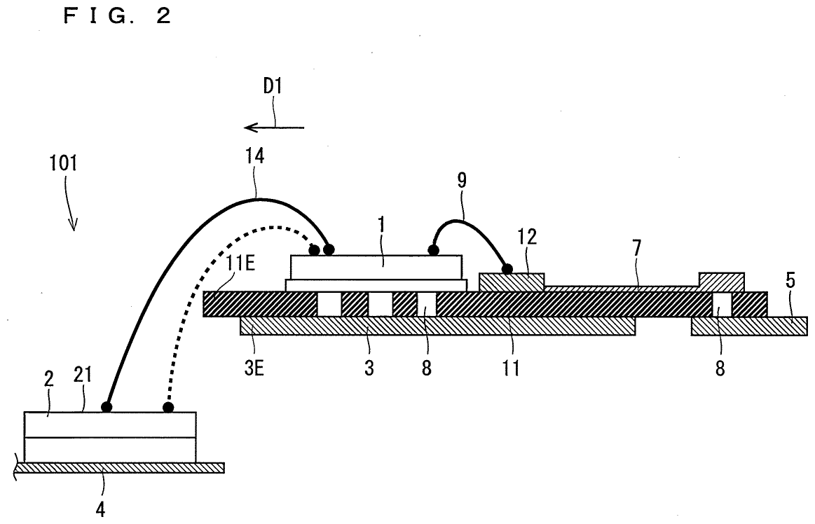

FIG. 1 is a top view of a semiconductor device 101 according to Embodiment 1. FIG. 2 is a cross-sectional view of the semiconductor device 101. The semiconductor device 101 is a transfer-molded power module.

As illustrated in FIGS. 1 and 2, the semiconductor device 101 according to Embodiment 1 includes a plurality of control chips 1a and 1b, a plurality of power chips 2a, 2b, 2c, 2d, 2e, and 2f, a first die pad 3, a plurality of second die pads 4c, 4d, 4e, and 4f, a plurality of control-side terminals 5, a plurality of power-side terminals 6, an insulating substrate 11, a plurality of circuit patterns 7, a plurality of wire pads 12, an insulating layer 13, and a molding resin 15. The first die pad 3, the plurality of second die pads 4c, 4d, 4e, and 4f, the plurality of control-side terminals 5, and the plurality of power-side terminals 6 are formed from a lead frame. Herein, the plurality of control chips 1a and 1b are also referred to as control chips 1 when being referred to in their entirety without being individually identified, and the plurality of power chips 2a, 2b, 2c, 2d, 2e, and 2f or the plurality of second die pads 4c, 4d, 4e, and 4f are also similarly referred to as power chips 2 or second die pads 4, respectively.

The plurality of control-side terminals 5 and the plurality of power-side terminals 6 are terminals to electrically connect the semiconductor device 101 to an external apparatus provided external to the semiconductor device 101. The plurality of control-side terminals 5 are terminals to control operation of the power chips 2 and to inform the external apparatus of abnormality of the semiconductor device 101. For example, the plurality of control-side terminals 5 are connected to a microcontroller. The plurality of power-side terminals 6 are paths of a principal current flowing through the semiconductor device 101 and are terminals to allow the principal current to flow to the external apparatus.

The semiconductor device 101 according to Embodiment 1 incorporates therein a three-phase AC output inverter circuit. Three phases herein refer to a U phase, a V phase, and a W phase. The control chip 1b is a low voltage integrated circuit (LVIC) to control driving of the power chip 2d of the U phase, the power chip 2e of the V phase, and the power chip 2f of the W phase. The three power chips 2a, 2b, and 2c constitute a P side. The control chip 1a is a high voltage integrated circuit (HVIC) to control driving of the power chips 2a, 2b, and 2c. The control chip 1a and the control chip 1b may be integrated as a single control chip. That is to say, the semiconductor device 101 is only required to include at least one control chip.

The power chips 2a, 2b, and 2c are mounted to the second die pad 4c. One of the power-side terminals 6 connected to the second die pad 4c is a P terminal. The power chip 2d is mounted to the second die pad 4d. One of the power-side terminals 6 connected to the second die pad 4d is a U terminal. The power chip 2e is mounted to the second die pad 4e. One of the power-side terminals 6 connected to the second die pad 4e is a V terminal. The power chip 2f is mounted to the second die pad 4f. One of the power-side terminals 6 connected to the second die pad 4f is a W terminal. When the power-side terminals 6 and the second die pads 4 are integrated, material can be minimized, and manufacturing steps can be simplified. They, however, may not be integrated. For example, the power-side terminals 6 and the second die pads 4 may be formed from separate members and connected by soldering, US bonding, and the like.

The control chips 1 are mounted to the first die pad 3. The first die pad 3 may be integrated with one or more of the control-side terminals 5. Integrating the first die pad 3 with the one or more of the control-side terminals 5 suppresses misalignment.

The insulating substrate 11 is provided on a top surface of the first die pad 3. The insulating substrate 11 is a PCB substrate, for example. The insulating substrate 11 is not required to have heat dissipation, so that an inexpensive substrate may be used as the insulating substrate 11. The circuit patterns 7 made of a conductive material are provided on a top surface of the insulating substrate 11. Furthermore, a plurality of through holes 8 extending through the thickness of the insulating substrate 11 are provided in the insulating substrate 11. Conductive materials are arranged in the through holes 8. The wire pads 12 are provided on the top surface of the insulating substrate 11.

One or more of the circuit patterns 7 are bonded to one or more of the control-side terminals 5 via one or more of the through holes 8 and are electrically connected to the one or more of the control-side terminals 5. For example, soldering is used for bonding between the one or more of the circuit patterns 7 and the one or more of the control-side terminals 5 via the one or more of the through holes 8. One or more of the through holes 8 are not electrically connected to the circuit patterns 7. The one or more of the through holes 8 not electrically connected to the circuit patterns 7 are bonded to the first die pad 3 by soldering and the like and serves to fix the insulating substrate 11 to the first die pad 3.

One or more of the circuit patterns 7 are electrically connected to one or more of the wire pads 12. First ends of first control wires 9 are connected to the wire pads 12. Second ends of the first control wires 9 are connected to the control chips 1. This configuration allows for transmission of a signal to control the power chips 2 from the control-side terminals 5 to the control chips 1 via the through holes 8, the circuit patterns 7, the wire pads 12, and the first control wires 9 in the semiconductor device 101.

The control chips 1 transmit the control signal to the power chips 2 via second control wires 14 and control operation of the power chips 2 as a three-phase AC output inverter. The second control wires 14 connect the control chips 1 and the power chips 2. Regions of the power chips 2 to which the second control wires 14 are connected are referred to as first connection regions 21. When the power chips 2 include metal-oxide-semiconductor field-effect transistors (MOSFETs), the first connection regions 21 are gate pads, and the second control wires 14 are gate wires. The power chips 2 are not limited to the MOSFETs and may be Schottky barrier diodes (SBDs), insulated gate bipolar transistors (IGBTs), or PN diodes. The control chips 1 are connected to the first die pad 3 via the one or more of the through holes 8 provided in the insulating substrate 11 and solder.

The power chips 2 and the power-side terminals 6 are connected by main wires 10. Regions of the power chips 2 to which the main wires 10 are connected are referred to as second connection regions 22. In contrast to the first control wires 9 and the second control wires 14, high currents flow through the main wires 10, so that the main wires 10 are formed to have larger thicknesses than the first control wires 9 and the second control wires 14 to suppress heat generation. The plurality of wire pads 12 are arranged close to the control chips 1, so that a longest first control wire 9 is shorter than a longest second control wire 14.

The control chips 1, the power chips 2, the first die pad 3, the second die pads 4, the insulating substrate 11, the plurality of circuit patterns 7, the plurality of wire pads 12, the first control wires 9, the main wires 10, the second control wires 14, and the insulating layer 13 are encapsulated by the molding resin 15. Thus, internal circuits, such as the control chips 1 and the power chips 2, are fixed, and external insulation of the semiconductor device 101 is secured. The control-side terminals 5 and the power-side terminals 6, however, protrude to be exposed from the molding resin 15 to enable external electrical connection. The second die pads 4 are connected to the insulating layer 13. The insulating layer 13 is formed of a member having a higher thermal conductivity than the molding resin 15, so that heat generated by the power chips 2 is efficiently dissipated.

Although not illustrated in FIGS. 1 and 2, the semiconductor device 101 may incorporate therein a boot strap diode (BSD). In this case, it is only necessary to provide an opening in the insulating substrate 11 at a position overlapping a position of the first die pad 3 to which the BSD is mounted in plan view and connect the BSD to the control-side terminals 5 through the opening by soldering and the like.

### A-2. Effects

The semiconductor device 101 according to Embodiment 1 includes the first die pad 3, the plurality of control chips 1a and 1b, the plurality of control-side terminals 5, the plurality of second die pads 4c to 4f, the plurality of power chips 2a to 2f, the plurality of power-side terminals 6, the insulating substrate 11, the plurality of conductive circuit patterns 7, the plurality of wire pads 12, the plurality of first control wires 9, the plurality of second control wires 14, and the molding resin 15. The plurality of control chips 1a and 1b are provided on a top side of the first die pad 3 and at a position overlapping the first die pad 3 in plan view and are electrically connected to the first die pad 3. The plurality of control-side terminals 5 are terminals to supply a signal to the plurality of control chips 1a and 1b. The plurality of power chips 2a to 2f are mounted to the respective second die pads 4c to 4f and controlled by the plurality of control chips 1a and 1b. The plurality of power-side terminals 6 are connected to the respective second die pads 4c to 4f. The insulating substrate 11 is provided on the top surface of the first die pad 3. The circuit patterns 7 are arranged on the top surface of the insulating substrate 11 and are electrically connected to the control-side terminals 5. The plurality of wire pads 12 are arranged on the top surface of the insulating substrate 11 and are electrically connected to the respective circuit patterns 7. The plurality of first control wires 9 electrically connect the plurality of wire pads 12 and the plurality of control chips 1a and 1b. The plurality of second control wires 14 electrically connect the plurality of control chips 1a and 1b and the first connection regions 21 of the plurality of power chips 2. The molding resin 15 encapsulates the plurality of control chips 1a and 1b, the plurality of power chips 2, the plurality of first control wires 9, and the plurality of second control wires 14. The first die pad 3, the plurality of second die pads 4, the plurality of control-side terminals 5, and the plurality of power-side terminals 6 are formed from the lead frame.

The above-mentioned configuration allows for transmission of the control signal from the control-side terminals 5 to the control chips 1a and 1b via the circuit patterns 7, the wire pads 12, and the first control wires 9 in the semiconductor device 101. The first control wires 9 can be shortened by arranging the wire pads 12 close to the control chips 1a and 1b. The longest first control wire 9 of the plurality of first control wires 9 can be shorter than the longest second control wire 14 of the plurality of second control wires 14. Deformation of the first control wires 9 and insulation failure associated with deformation during encapsulation by the molding resin 15 can thereby be suppressed.

As illustrated in FIG. 2, the second control wires 14 extend in a first direction D1 from the control chips 1 to the power chips 2. An end 11E of the insulating substrate 11 in the first direction D1 protrudes beyond an end 3E of the first die pad 3 in the first direction D1 toward the first connection regions 21 of the plurality of power chips 2. The above-mentioned configuration brings the second control wires 14 into contact with the end 11E of the insulating substrate 11 as indicated by a dashed line in FIG. 2 even if the second control wires 14 are deformed in a molding step. Contact of the second control wires 14 with the end 3E of the first die pad 3 and insulation failure associated with contact are thereby suppressed.

In the semiconductor device 101, the plurality of control chips 1a and 1b are mounted to the top surface of the insulating substrate 11 and are electrically connected to the first die pad 3 via the one or more of the through holes 8 provided in the insulating substrate 11. As described above, the control chips 1a and 1b are mounted not to the first die pad 3 but to the insulating substrate 11, so that there is no need to change the lead frame for low volume types of products to enable suppression of an increase in cost due to use of a common member. Furthermore, a floating electrode difficult to be formed from the lead frame or a plurality of elements having different reference voltages, such as insulating drives, can be mounted to the insulating substrate 11.

By finely forming the circuit patterns 7 on the insulating substrate 11, areas of the control chips 1a and 1b can be reduced, and, as a result, areas of the power chips 2 and their die areas can be increased.

Furthermore, current capability can be increased, that is, power density can be improved without changing an outer shape of a general-purpose package.

### A-3. Modifications

A high heat resistant material having a heat resistance equal to or higher than a curing temperature of the molding resin 15 may be used for the insulating substrate 11. A power semiconductor device can thereby be formed in a general-purpose package or with a general-purpose pin assignment. A common material and a common step allow for reduction in cost, and, in an application set, a common substrate allows for reduction in total cost.

A MOSFET made of a wide bandgap material, such as SiC, GaN, and Ga₂O₃, may be mounted to the power chips 2. While the MOSFET is a high breakdown voltage unipolar device, thus has a low switching loss, and can perform high-carrier operation, use of a gate driver having a high narrow pulse reactivity (e.g., of a micro transformer scheme) can improve pulse response and improve waveform generation efficiency.

In formation in a package having the same size, use of a control substrate can reduce a wiring area and thus can increase output capability of an IC driver. That is to say, a speed of a power semiconductor chip can be increased. While a gate driver having a multiple-chip configuration, such as a micro transformer, requires a floating electrode or a power supply, use of the insulating substrate 11 provides a degree of freedom to a mount position, so that a module area can be reduced.

### B. Embodiment 2

### B-1. Configuration

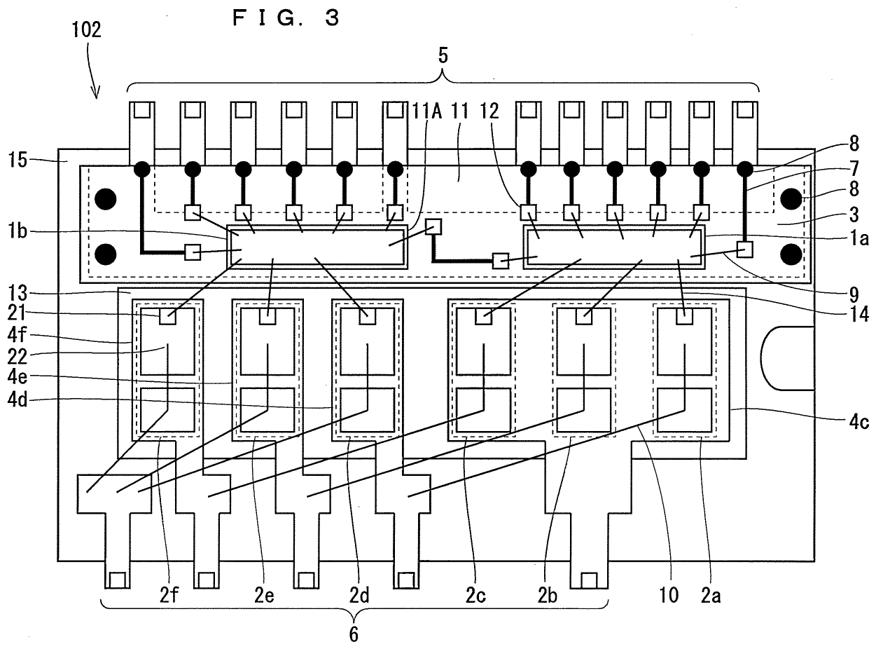

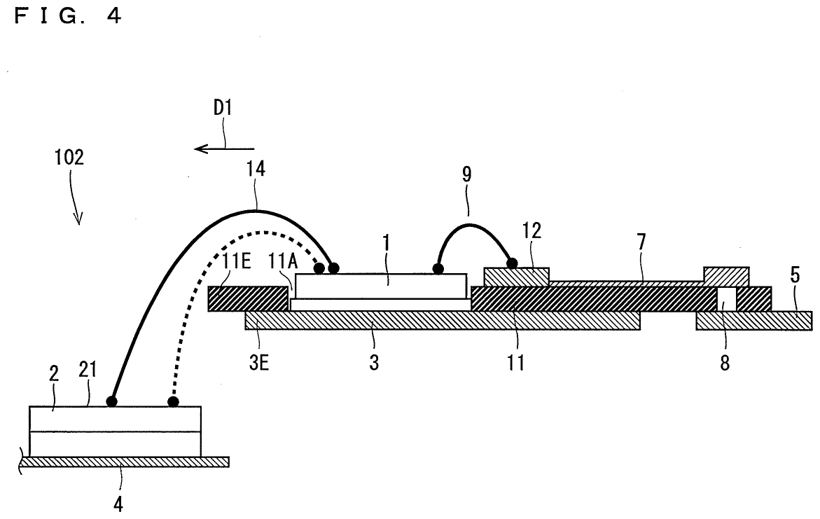

FIG. 3 is a top view of a semiconductor device 102 according to Embodiment 2. FIG. 4 is a cross-sectional view of the semiconductor device 102.

The semiconductor device 102 differs from the semiconductor device 101 according to Embodiment 1 in that the control chips 1a and 1b are bonded to the first die pad 3 by a conductive bonding material, such as solder. The insulating substrate 11 has an opening 11A, and the control chips 1a and 1b are bonded to the top surface of the first die pad 3 in the opening 11A. In other words, the control chips 1a and 1b are provided at positions overlapping the opening 11A of the insulating substrate 11 in plan view.

### B-2. Effects

In the semiconductor device 102 according to Embodiment 2, the control chips 1a and 1b are mounted to the top surface of the first die pad 3 in the opening 11A provided in the insulating substrate 11. The first die pad 3 formed from the lead frame of copper and the like has higher heat dissipation than the insulating substrate 11, so that the semiconductor device 102 has a configuration having higher heat dissipation than the semiconductor device 101 according to Embodiment 1. An increase in temperature of the semiconductor device 102 can thus be suppressed at a high voltage or during high-carrier operation.

### C. Embodiment 3

### C-1. Configuration

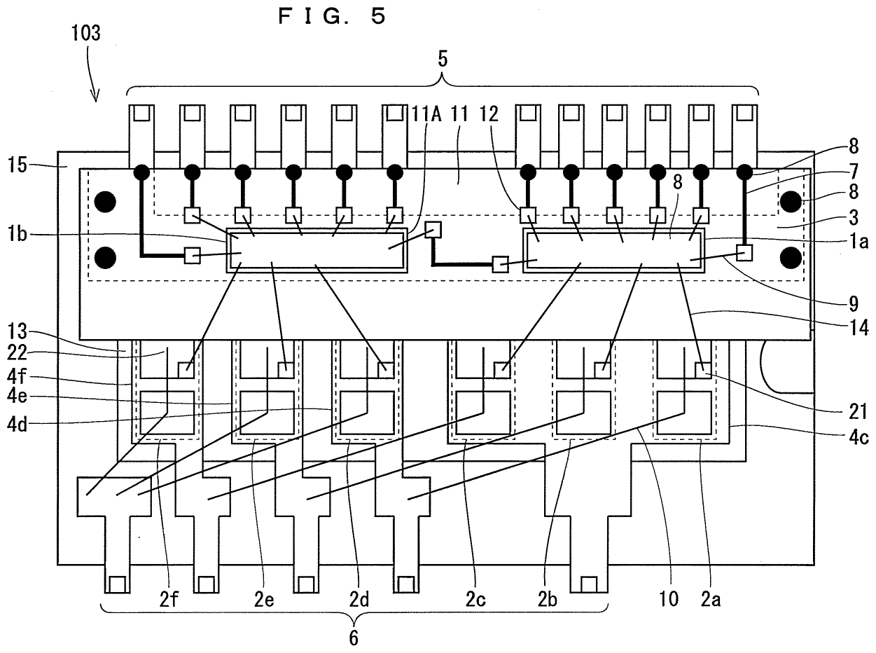

FIG. 5 is a top view of a semiconductor device 103 according to Embodiment 3.

The semiconductor device 103 differs from the semiconductor device 102 according to Embodiment 2 in that the plurality of power chips 2 and the plurality of second die pads 4 are arranged below the insulating substrate 11 to partially overlap the insulating substrate 11 in plan view. The semiconductor device 103 may be the semiconductor device 101 according to Embodiment 1 having been modified so that the plurality of power chips 2 and the plurality of second die pads 4 to which the plurality of power chips 2 are mounted are partially arranged below the insulating substrate 11.

On the other hand, the first connection regions 21 of the plurality of power chips 2 to which the second control wires 14 are connected and the second connection regions 22 of the plurality of power chips 2 to which the main wires 10 are connected do not overlap the insulating substrate 11 in plan view.

In the semiconductor device 103 according to Embodiment 3, the plurality of power chips 2 and the plurality of second die pads 4c to 4f are arranged below the insulating substrate 11 to partially overlap the insulating substrate 11 in plan view. The connection regions of the plurality of power chips 2 do not overlap the insulating substrate 11 in plan view. The above-mentioned configuration allows for an increase in area of the power chips 2 in a general-purpose package and improvement in power density in the semiconductor device 103.

While the preferred embodiments and the like have been described in detail above, various modifications and replacements can be made on the above-mentioned embodiments and the like without being limited to the above-mentioned embodiments and the like and without departing from the scope of the claims.

Various aspects of the present disclosure will collectively be described below as appendices.

### Appendix 1

A semiconductor device comprising:
a first die pad;
at least one control chip provided on a top side of the first die pad and at a position overlapping the first die pad in plan view, the at least one control chip being electrically connected to the first die pad;
a plurality of control-side terminals to supply a signal to the at least one control chip;
a plurality of second die pads;
a plurality of power chips mounted to the respective second die pads and controlled by the at least one control chip;
a plurality of power-side terminals connected to the respective second die pads;
an insulating substrate provided on a top surface of the first die pad;
a plurality of conductive circuit patterns arranged on a top surface of the insulating substrate and electrically connected to the control-side terminals;
a plurality of wire pads arranged on the top surface of the insulating substrate and electrically connected to the respective circuit patterns;
a plurality of first control wires electrically connecting the plurality of wire pads and the at least one control chip;
a plurality of second control wires electrically connecting the at least one control chip and first connection regions of the plurality of power chips; and
a molding resin encapsulating the at least one control chip, the plurality of power chips, the plurality of first control wires, and the plurality of second control wires, wherein
the first die pad, the plurality of second die pads, the plurality of control-side terminals, and the plurality of power-side terminals are formed from a lead frame.

### Appendix 2

The semiconductor device according to Appendix 1, wherein
a longest first control wire of the plurality of first control wires is shorter than a longest second control wire of the plurality of second control wires.

### Appendix 3

The semiconductor device according to Appendix 1 or 2, wherein
the second control wires extend in a first direction from the at least one control chip to the power chips, and
an end of the insulating substrate in the first direction protrudes beyond an end of the first die pad in the first direction toward the first connection regions of the plurality of power chips.

### Appendix 4

The semiconductor device according to any one of Appendices 1 to 3, wherein
the at least one control chip is mounted to the top surface of the insulating substrate and is electrically connected to the first die pad via a through hole provided in the insulating substrate.

### Appendix 5

The semiconductor device according to any one of Appendices 1 to 3, wherein
the at least one control chip is mounted to a top surface of the first die pad in an opening provided in the insulating substrate.

### Appendix 6

The semiconductor device according to any one of Appendices 1 to 5, wherein
the plurality of power chips and the second die pads are arranged below the insulating substrate to partially overlap the insulating substrate in plan view, and
the first connection regions of the plurality of power chips do not overlap the insulating substrate in plan view.

### Appendix 7

The semiconductor device according to any one of Appendices 1 to 6, wherein
the insulating substrate is made of a material having a heat resistance equal to or higher than a curing temperature of the molding resin.

### Appendix 8

The semiconductor device according to any one of Appendices 1 to 7, wherein
the power chips include a MOSFET made of a wide bandgap material.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a first die pad;
at least one control chip provided on a top side of the first die pad and at a position overlapping the first die pad in plan view, the at least one control chip being electrically connected to the first die pad;
a plurality of control-side terminals to supply a signal to the at least one control chip;
a plurality of second die pads;
a plurality of power chips mounted to the respective second die pads and controlled by the at least one control chip;
a plurality of power-side terminals connected to the respective second die pads;
an insulating substrate provided on a top surface of the first die pad;
a plurality of conductive circuit patterns arranged on a top surface of the insulating substrate and electrically connected to the control-side terminals;
a plurality of wire pads arranged on the top surface of the insulating substrate and electrically connected to the respective circuit patterns;
a plurality of first control wires electrically connecting the plurality of wire pads and the at least one control chip;
a plurality of second control wires electrically connecting the at least one control chip and first connection regions of the plurality of power chips; and
a molding resin encapsulating the at least one control chip, the plurality of power chips, the plurality of first control wires, and the plurality of second control wires, wherein
the first die pad, the plurality of second die pads, the plurality of control-side terminals, and the plurality of power-side terminals are formed from a lead frame.

2. The semiconductor device according to claim 1, wherein
a longest first control wire of the plurality of first control wires is shorter than a longest second control wire of the plurality of second control wires.

3. The semiconductor device according to claim 1, wherein
the second control wires extend in a first direction from the at least one control chip to the power chips, and
an end of the insulating substrate in the first direction protrudes beyond an end of the first die pad in the first direction toward the first connection regions of the plurality of power chips.

4. The semiconductor device according to claim 1, wherein
the at least one control chip is mounted to the top surface of the insulating substrate and is electrically connected to the first die pad via a through hole provided in the insulating substrate.

5. The semiconductor device according to claim 1, wherein
the at least one control chip is mounted to a top surface of the first die pad in an opening provided in the insulating substrate.

6. The semiconductor device according to claim 1, wherein
the plurality of power chips and the second die pads are arranged below the insulating substrate to partially overlap the insulating substrate in plan view, and
the first connection regions of the plurality of power chips do not overlap the insulating substrate in plan view.

7. The semiconductor device according to claim 1, wherein
the insulating substrate is made of a material having a heat resistance equal to or higher than a curing temperature of the molding resin.

8. The semiconductor device according to claim 1, wherein
the power chips include a MOSFET made of a wide bandgap material.
